(19) United States
(12) Patent Application Publication
(10) Pub. No.: US 2011/0012108 A1
(43) Pub. Date: Jan. 20, 2011

(54) Semiconductor device having process failure detection circuit and semiconductor device production method

(75) Inventor: Toru Fujimura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/801,856

(22) Filed: Jun. 29, 2010

(30) Foreign Application Priority Data
Jul. 17, 2009 (JP) 2009-168861

(51) Int. Cl. H01L 23/544; H01L 21/66

(52) U.S. Cl. 257/48; 438/18; 257/E23.179; 257/E21.53

(57) ABSTRACT

A semiconductor device includes a cell array and a plurality of process failure detection circuits each having a layout pattern substantially identical to that of a cell of the cell array in a dummy region arranged around the cell array. Each of the process failure detection circuits includes a dummy pattern that equalizes a degree of density/sparsity of a peripheral part of the cell array with that of a central part of the cell array. The process failure detection circuits include a process failure detection circuit having a layout pattern formed with a stricter pattern margin in at least one manufacturing process, compared with the layout pattern of the cell of the cell array.

### TECHNICAL FIELD

### Reference to Related Application

This application is based upon and claims the benefit of the priority of Japanese patent application No. 2009-168861, filed on Jul. 17, 2009, the disclosure of which is incorporated herein in its entirety by reference thereto.

The present invention relates to a semiconductor device and a semiconductor device production method. In particular, the present invention relates to a semiconductor device including a process failure detection circuit and a semiconductor device production control method by using the process failure detection circuit.

### BACKGROUND

Semiconductor wafers are produced through various manufacturing processes. However, since it is difficult to directly examine conditions of a semiconductor wafer on the spot after each of the manufacturing processes, various methods are used to control these manufacturing processes. In one method, other than semiconductor wafers manufactured as products, a test element group (TEG) wafer is manufactured in a manufacturing line. The TEG wafer includes elements for examining conditions of semiconductor waters or finding design or manufacturing problems with the semiconductor devices after each of the manufacturing processes. Such TEG wafer is used for surface inspection (or appearance inspection) and device 30, characteristics measurement, and in this way, the semiconductor wafer manufacturing line is controlled.

However, during manufacture of the above dedicated TEG wafer in the manufacturing line, actual products cannot be manufactured. Further, it is time-consuming to change the manufacturing line between manufacture of the dedicated TEG wafers and that of the product wafers.

In addition, since the actual products and the TEG wafers have different layout patterns and functions, the correlation between characteristics of the actual products and evaluation results of the TEG wafers needs to be examined.

Furthermore, since these product and TEG wafers are different semiconductor wafers, manufacturing conditions of a failure product semiconductor wafer cannot always be recreated. When a failure is found in an actual product, it may be difficult to determine the cause of the failure within a short time.

In view of such problems, manufacturing of a semiconductor device is performed with controlling by arranging a TEG pattern on a scribe line in an actual product semiconductor wafer or in a region of a product semiconductor chip.

Patent Document 1 discloses a conventional semiconductor device including a TEG pattern, and FIG. 10 is a plan view of a chip configuration of the semiconductor device. This semiconductor device disclosed in Patent Document 1 has a gate array and a test pattern 6 (process failure detection circuit) used as a TEG in an unused available region 5 of basic gate array cells 1. Paragraph 0006 of Patent Document 1 states that “in a gate array, basic gate array cells are regularly arranged in advance on the whole surface in columns, and desired logic circuits are wired by computer-aided design (CAD). Thus, since the circuit configuration is determined by the wirings, unwired portions, namely, available regions remain.

Patent Document 1 discloses example 1 in which process failure detection circuits (test patterns) are formed by using underlying metal wirings alone, example 2 in which topmost layer metal wirings are formed with a process margin greater than that of product circuits, and example 3 in which contact holes under metal wirings are formed with a process margin greater than that of product circuits.

Patent Document 2 discloses arranging dummy cells around a memory cell array to prevent pattern variations.

### Patent Document 1

Japanese Patent Kokai Publication No. JP-H08-088282 A

### Patent Document 2

Japanese Patent Kokai Publication No. JP2003-282731 A, which corresponds to US Patent Application Publication No. US2003/0235091 A1.

### SUMMARY

The entire disclosure of above-identified Patent Documents are incorporated herein by reference thereto.

Analysis will be hereinafter made based on the present invention. Patent Document 1 is directed to a gate array in which basic gate array cells 1 are formed on the whole chip surface in advance. Based on the gate array, only the necessary cells required by a product specification are used to design the product, and thus, unused regions often remain. However, in the case of a cell-based semiconductor device, since the layout of the base layer thereof is also designed by a product specification, such unused regions do not remain. Further, when a memory cell is used as a process failure detection circuit, a memory decode circuit or read/write circuit needs to be additionally arranged.

According to a first aspect of the present invention, there is provided a semiconductor device including a cell array and a plurality of process failure detection circuits cach having a layout pattern substantially identical to that of a cell of the cell array in a dummy region arranged around the cell array.

According to a second aspect of the present invention, there is provided a method of manufacturing of a semiconductor device under a specific control. The semiconductor device includes a cell array and a plurality of types of process failure detection circuits, each having a layout pattern substantially identical to that of a cell of the cell array in a dummy region around the cell array, each type of the process failure detection circuit having a layout pattern formed with a stricter pattern margin in a different manufacturing process of the semiconductor device, compared with the layout pattern of the cell of the cell array. The method includes: carrying out a surface inspection of a first process by using a first type process failure detection circuit of the plurality types of the detection circuit having a layout pattern formed with a stricter pattern margin in the first process, the first process being a one process in a wafer-level manufacturing processes of the semiconductor device; and providing feedback about a manufacturing condition to the first process when a problem is found in the surface inspection of the first process. The method further includes: carrying out a function test on the plurality of types of process failure detection circuits after completion of the wafer-level manufacturing processes; determining a problematic manufacturing process by using a result of the function test on the plurality of types of process failure detection circuits when a problem is found in the function test; and providing feedback about manufacturing condition of the problematic manufacturing processes.

According to the present invention, since a process failure detection circuit is arranged in a dummy region around a cell array, the chip area is not increased by the process failure detection circuit. Namely, the process failure detection circuit is allowed to function as a dummy pattern.

### BRIEF DESCRIPTION OF THE DRAWINGS

FIG. 1A is an overall layout of a semiconductor device according to an example of the present invention, FIG. 1B is an enlarged layout of a memory macro part in FIG. 1A, and FIG. 1C is an enlarged layout of a process failure detection circuit array and part of the memory cell array in one memory block of the memory macro part in FIG. 1B.

FIGS. 2A and 2B illustrate configuration examples of process failure detection circuits according to an example. FIG. 2A illustrates a layout pattern of a field layer of a field failure detection circuit and

FIG. 2B illustrates a layout pattern of a gate layer of a gate failure detection circuit.

FIG. 3 illustrates actual-size target values of the process failure detection circuits according to an example.

FIG. 4 is a layout of various type process failure detection circuits for detecting failures in various processes according to an example.

FIG. 5 is a layout of a contact failure detection circuit according to an example.

FIGS. 6A to 6C illustrate typical values and upper and lower limits of the size of a contact or a via, respectively.

FIG. 7 illustrates examples of a failure bit map of a plurality of processes by using a plurality type of process failure detection circuits according to an example.

FIGS. 8A to 8C are wafer-level failure bit maps of products, field failure detection circuits, and contact failure detection circuits according to an example, respectively.

FIG. 9 is a flow chart illustrating a method of manufacturing a semiconductor device under a control by using the process failure detection circuits according to an example.

FIG. 10 is a plan view of a chip configuration of a conventional semiconductor device disclosed in Patent Document 1.

### PREFERRED MODES

Before examples of the present invention are described in detail, an outline of exemplary embodiments of the present invention will be first described. The drawings and reference characters referred to in the description of the outline are used to illustrate examples of the exemplary embodiments. Therefore, variations of the exemplary embodiments according to the present invention are not limited by the drawings and reference characters.

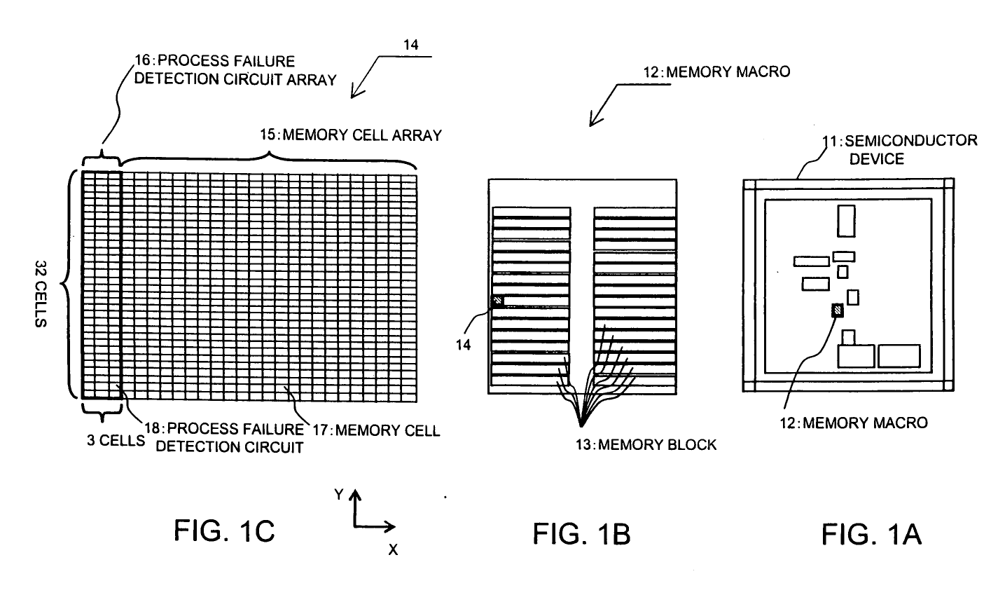

A semiconductor device according to an exemplary embodiment of the present invention will be hereinafter described. For example, as illustrated in FIG. 1, a semiconductor device 11 includes a cell array 15 and a plurality of process failure detection circuits 18 each having a layout pattern substantially identical to that of a cell 17 of the cell array 15 in a dummy region 16 arranged around the cell array 15. Thus, the chip area is not increased by arranging the process failure detection circuit 18. Each of the process failure detection circuits 17 in the dummy region 16 includes dummy pattern. The dummy pattern equalizes a degree of density/sparsity of a peripheral part of the cell array 15 with that of a central part of the cell array 15. Since the process failure detection circuit 18 has a shape substantially identical to that of the cell 17 of the cell array 15, the arrangement of the process failure detection circuit 18 around the cell array 15 does not cause peripheral pattern variations between the cell 17 in the central part and the cell 17 in the peripheral part of the cell array 15. Thus, no circuit characteristics difference is caused between the cell 17 in the central part and the cell 17 in the peripheral part of the cell array 15. The cell array may be a cell array of an analog-to-digital (AD) converter, a multiplier, or the like, other than the memory cell array 15. The dummy pattern functions in a similar way to the dummy cell disclosed in Patent Document 2.

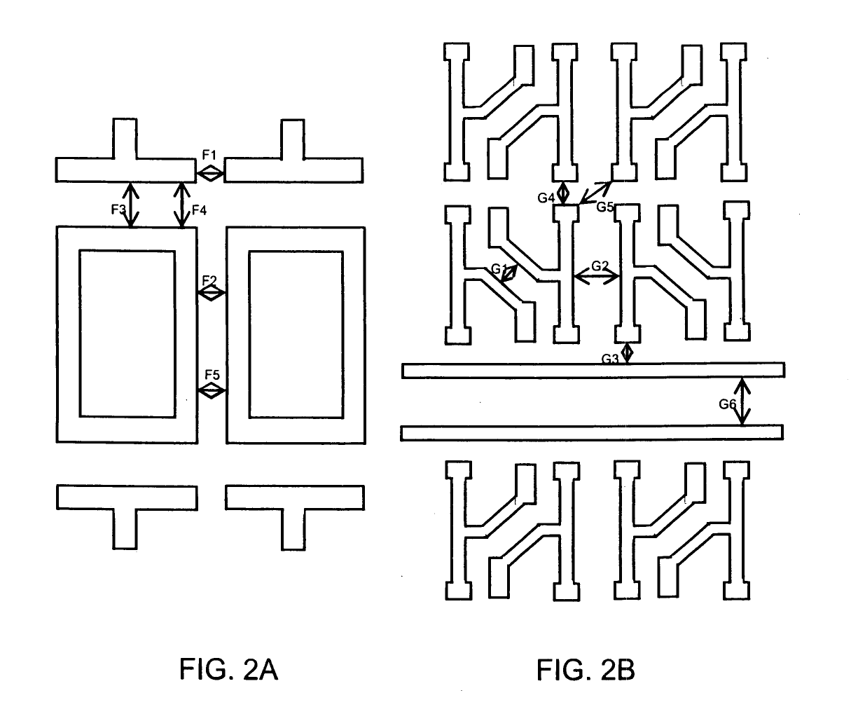

Further, for example, as illustrated in FIG. 2, the process failure detection circuit 18 has a layout pattern formed with a stricter pattern margin in at least one manufacturing process, compared with the layout pattern of the cell 17 of the cell array 15. Since a stricter pattern margin is used, the process failure detection circuit 18 can be arranged at the same intervals as the cell 17 of the cell array 15. For example, if the process failure detection circuit 18 is formed with a process margin greater than that of a product as disclosed in Patent Document 1, the process failure detection circuit 18 cannot be arranged at the same intervals as the cell 17 of the cell array 15.

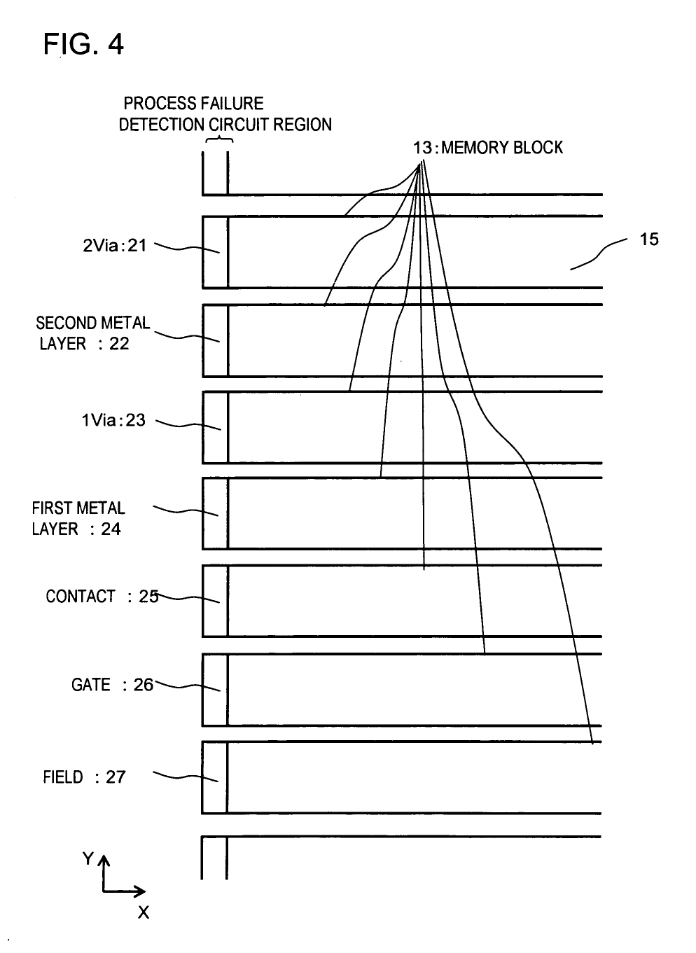

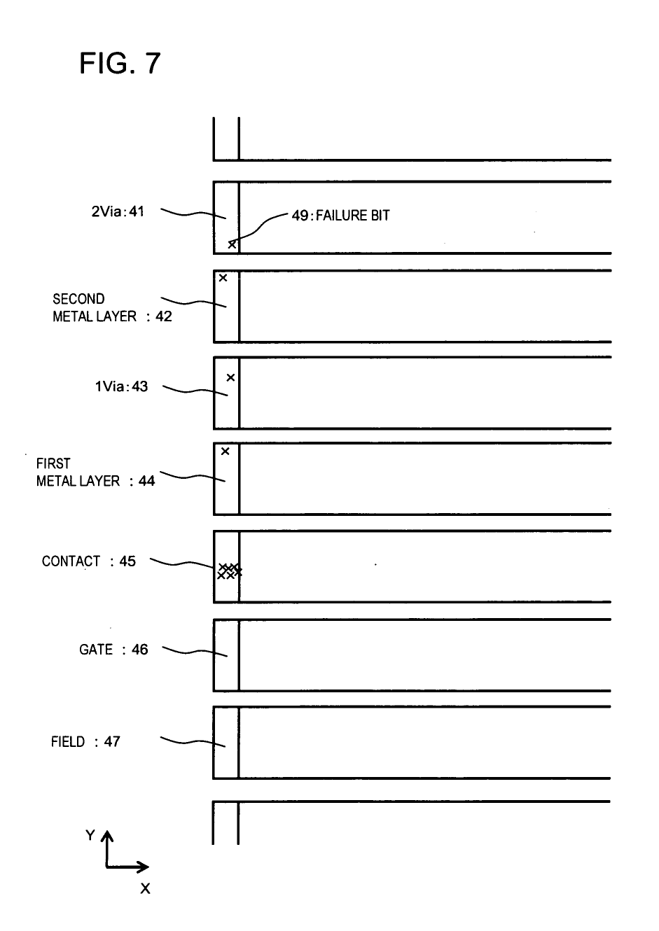

Further, for example, as illustrated in FIG. 4, the semiconductor device includes a plurality types of the process failure detection circuits (21 to 27) each having a layout pattern formed with a stricter pattern margin in a different manufacturing process, compared with the layout pattern of the cell 17 of the cell array 15. Thus, by creating failure bit maps as illustrated in FIG. 7, manufacturing processes causing failures can be determined easily. The process failure detection circuit 18 may be a wiring process failure detection circuit (21 to 24, for example) formed with a stricter wiring pattern including any of wirings and vias, or a base layer process failure detection circuit (25 to 27, for example) formed with a stricter base layer pattern including any of gates, contacts, and fields, compared with the layout pattern of the cell 17 of the cell array 15.

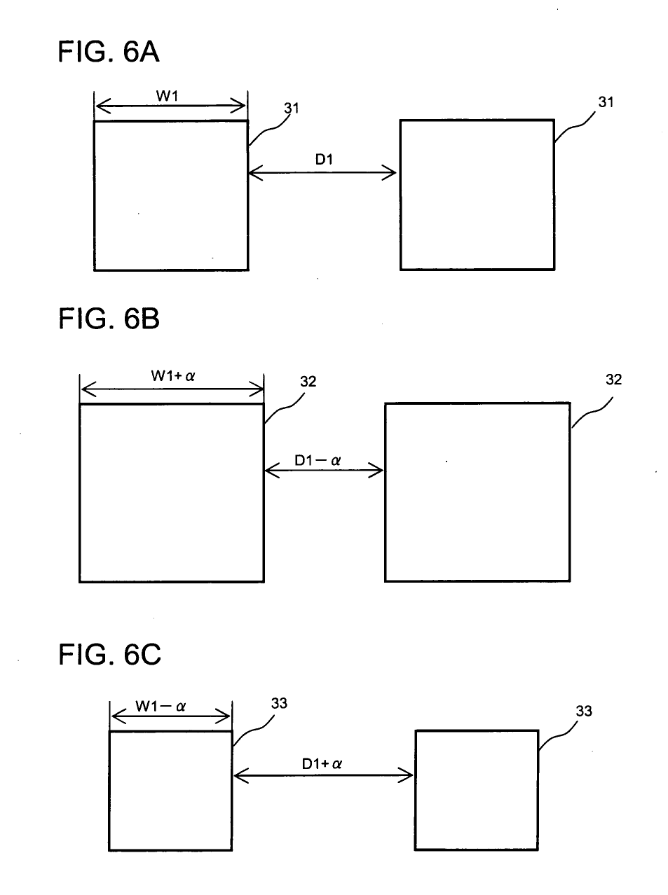

Further, for example, as illustrated in FIG. 6, when the pattern margin is determined based on first and second pattern sizes (W1 and D1, for example), the process failure detection circuit 18 may be a process failure detection circuit (FIG. 6B) formed by increasing the first pattern size toward an upper limit or a process failure detection circuit (FIG. 6C) formed by decreasing the first pattern size toward a lower limit without changing a total value (W1+D1) of the first and second pattern sizes.

Further, the cell array is a memory cell array 15, and the process failure detection circuit 18 can share a read/write circuit with the memory cell array 15. Since the process failure detection circuit 18 is adjacent to the memory cell array 15 and the bit and word lines extend in the circuit 18 and the array 15 at the same intervals, the process failure detection circuit 18 can share a read/write circuit with the memory cell array 15 easily.

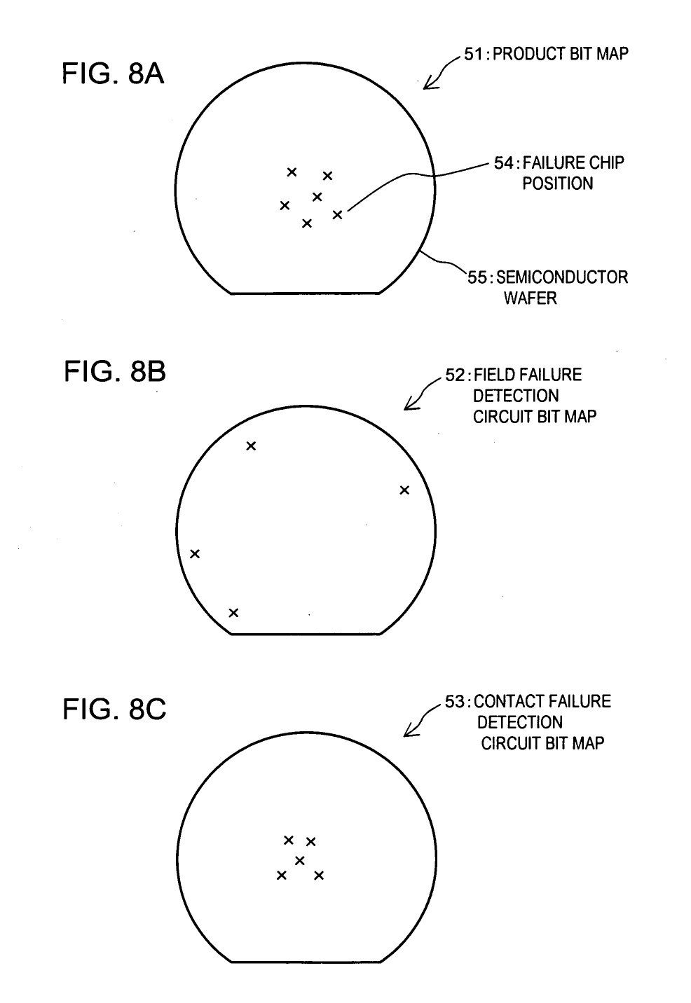

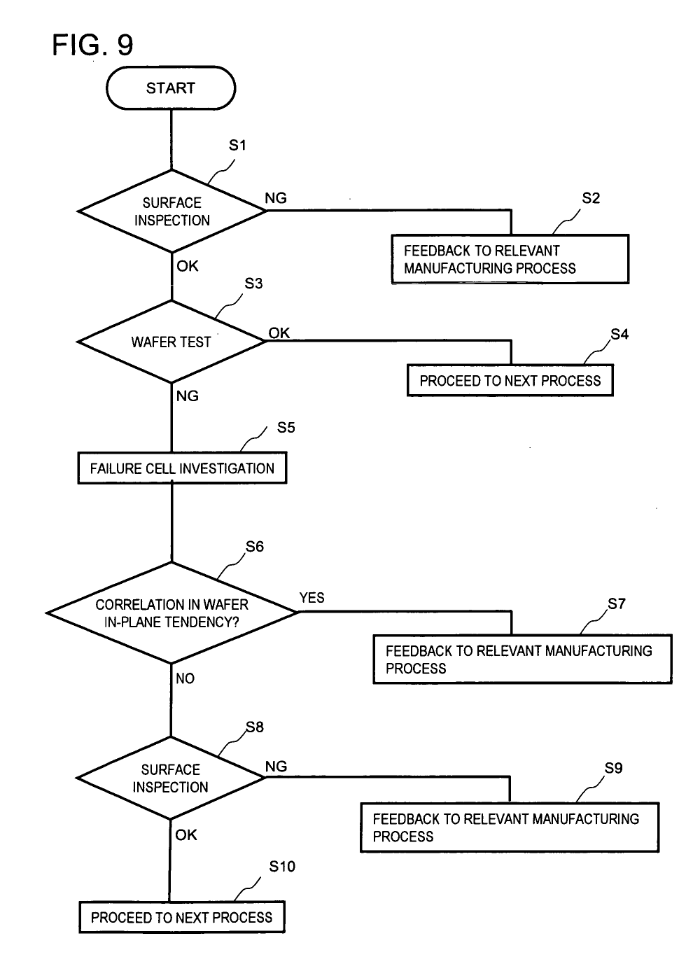

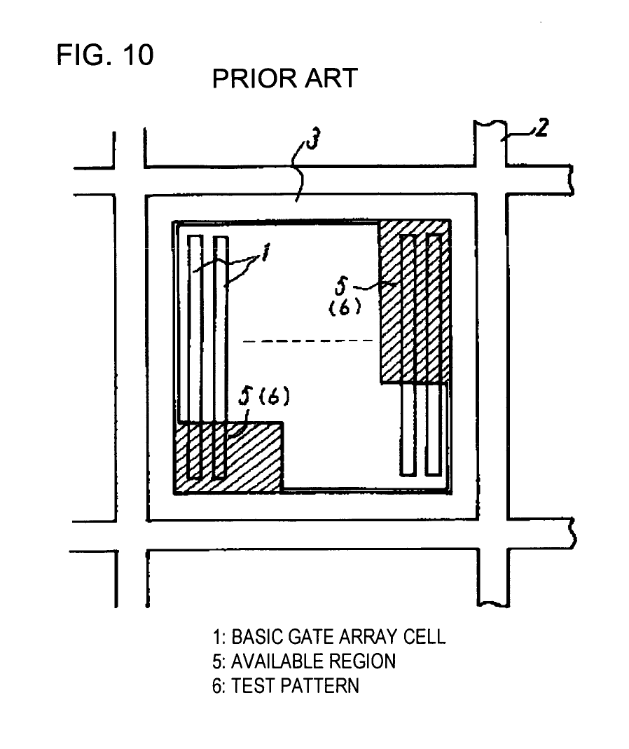

Further, a method for managing manufacture of a semiconductor device according to an exemplary embodiment of the present invention will be described with reference to FIG. 9. A semiconductor device 11 includes a cell array 15 and a plurality types of process failure detection circuits (for example, 21 to 27 in FIG. 4), each having a layout pattern substantially identical to that of a cell 17 of the cell array 15 in a dummy region 16 around the cell array 15 and each formed with a stricter pattern margin in a different manufacturing process of the semiconductor device 11. The method includes: carrying out a surface inspection by using a process failure detection circuit pattern (FIGS. 2A, 2B, for example) formed with a stricter pattern margin in one of the wafer-level manufacturing processes of the semiconductor device 11 (step S1); providing feedback about manufacturing conditions to the manufacturing process if a problem is found (step S2); carrying out a function test on the plurality of types of process failure detection circuits (21 to 27 in FIG. 4) after completion of the wafer-level manufacturing processes and if no problems are found by the surface inspection and determining, if a problem is found, a problematic manufacturing process by using the type of the problematic process failure detection circuit 18 (step S5); and providing feedback about manufacturing condition of the problematic manufacturing process (S7). The determining a problematic manufacturing process includes analyzing a position of a failure semiconductor device determined by a function test of total function of the semiconductor device found on the wafer (FIG. 8A, for example), the position of the failure for each type of the process failure detection circuit 18 found on the wafer (FIGS. 8B, 8C), and failure occurrence frequency; and determining the problematic manufacturing processes based on a result of the analyzing (step S6).

The cell array is a memory cell array 15, and a function test of the process failure detection circuit 18 is carried out by performing read/write access to the process failure detection circuit 18 via the memory cell array 15. Namely, since the word and bit lines extend at the same intervals in the memory cell array 15 and the process failure detection circuit 18, the read/write circuit can be shared easily. Examples will be hereinafter described in detail with reference to the accompanying drawings.

### Example 1

FIG. 1A is an overall layout of a semiconductor device 11 according to example 1 of the present invention. The semiconductor device 11 includes a plurality of macroblocks including a memory macro 12. FIG. 1B is an enlarged layout of the memory macro 12 in FIG. 1A, and as illustrated, the memory macro 12 includes 16 memory blocks 13 on each of the left and right sides thereof. In each of the memory blocks 13, memory cells of 32 bits are arranged along the Y-axis (vertically in FIGS. 1A-1C) and memory cells of 128 bits are arranged along the X-axis (horizontally in FIGS. 1A-1C) perpendicular to the Y-axis. Further, in each of the memory blocks 13, 128 word lines and 32 bit lines extend in parallel to the Y-axis and the X-axis, respectively, and each memory cell is arranged at the intersection of a word line and a bit line. Namely, each of the memory blocks 13 includes memory cells of 32 bits×128 bits. In addition, at an end of each of the memory blocks 13, a dummy region is arranged so that variations of the layout pattern are not caused between the central part and the peripheral part of the memory block 13.

FIG. 1C is an enlarged view of a peripheral region 14 in FIG. 1B including such dummy region in a single memory block 13. Namely, FIG. 1C illustrates a layout of the region 14 at an end of the single memory block 13, and a process failure detection circuit array 16 is arranged in a peripheral part of an end of a memory cell array 15. In the process failure detection circuit array 16, process failure detection circuits 18 are arranged in three columns along the X-axis and in 32 rows along the Y-axis (the same as the memory cell array 15). Namely, at an end of each of the memory blocks 13 along the X-axis, process failure detection circuits 18 of 96 bits (3 bits×32 bits) can be arranged. Thus, if each of the 16 memory blocks 13 is provided with these process failure detection circuits 18 at an end thereof along the X-axis, a single memory macro 12 can include 1,536 process failure detection circuits 18 (96 bits×16 blocks). The individual cells in the process failure detection circuit array 16 can have slightly different sizes from each other. The process failure detection circuits 18 are formed by the cells of the process failure detection circuit array 16, and these cells are basically identical to the memory cells 17 forming the memory cell array 15, except that the process failure detection circuits 18 are formed with a stricter size margin in a process, compared with the memory cells 17 of the memory cell array 15. Further, the process failure detection circuit array 16 and the memory cell array 15 share the bit lines extending in parallel to the X-axis. The word lines extend in parallel to the Y-axis. During a test, data can be read from and written in the process failure detection circuits 18 from the outside of the memory block 13 via the memory cell array 15 through the bit lines shared with the memory cell array 15. Thus, there is no need to arrange a dedicated read/write circuit for the process failure detection circuit array 16.

In FIG. 1C, while the process failure detection circuit array 16 is arranged in a region at an end of each of the memory blocks 13 along the X-axis, the process failure detection circuits 18 of the process failure detection circuit array 16 have a function as a dummy pattern. A dummy pattern needs to be arranged around the memory cell array 15. However, if the memory cell array 15 of another memory block 13 is adjacently arranged along the Y-axis, there is no need to arrange a dummy pattern. While cells are regularly arranged in the memory cell array 15, the dummy pattern is arranged in a certain area in a peripheral part of the memory cell array 15 where the regularity of the arrangement of the memory cell array 15 discontinues. Characteristics of the memory cells 17 may be changed because of peripheral pattern variations between memory cells 17 arranged in the central part and memory cells 17 arranged in the peripheral part of the memory cell array 15, and therefore, the dummy pattern is arranged to prevent such change of characteristics of the memory cells 17. While such dummy pattern is arranged around the memory cell array 15 of the memory macro 12, the process failure detection circuits 18 are arranged in part of or the entire area of the region where this dummy pattern is arranged. Thus, the chip area is not increased by arranging the process failure detection circuits 18. In addition, each of the process failure detection circuits 18 has a shape substantially identical to the memory cell 17, and the process failure detection circuits 18 can be arranged at the same intervals as the memory cells 17. Thus, the process failure detection circuits 18 can function as a dummy pattern.

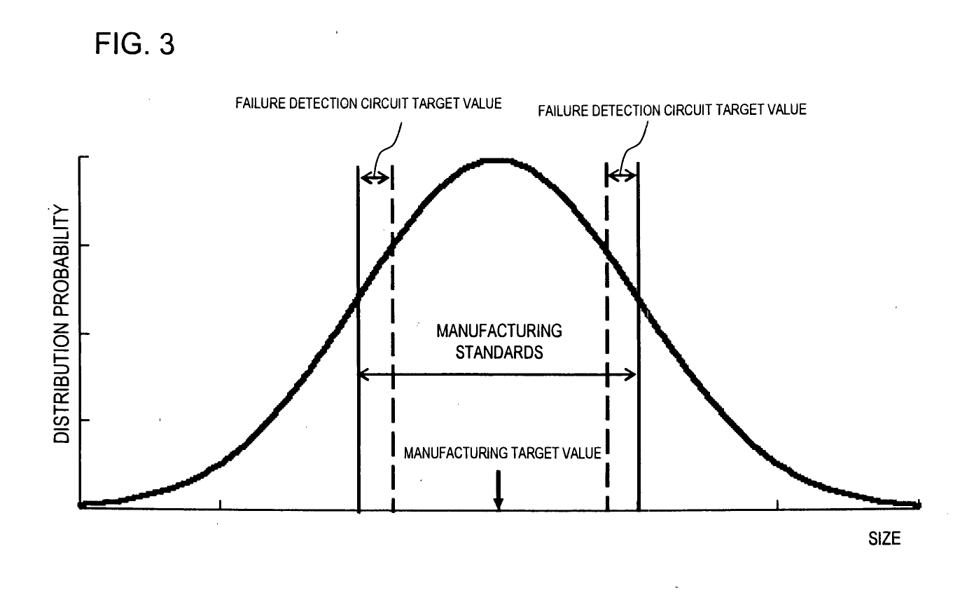

Next, the process failure detection circuit 18 will be described in detail. FIG. 2A illustrates a layout pattern of a field layer of a field failure detection circuit, which is one of the process failure detection circuits 18 and which is used for detecting a field failure. The field failure detection circuit has the same circuit configuration, layout pattern, and function as those of the memory cell 17 of the memory cell array 15, except that the field layer has slightly different layout pattern sizes at some parts from those of the memory cell 17. More specifically, at the parts denoted by reference characters F1 to F5 in FIG. 2A, the field layer of the field failure detection circuit has slightly stricter layout pattern sizes than those of the memory cell 17 of the memory cell array 15. As illustrated in FIG. 3, these stricter layout pattern sizes of the process failure detection circuit 18 are determined to be close to upper and lower limits defined by product manufacturing standards.

FIG. 2B illustrates a layout pattern of a gate layer of a gate failure detection circuit, which is one of the process failure detection circuits 18 and which is used for detecting a gate failure. At the parts denoted by reference characters G1 to G6 in FIG. 2B, the gate layer of the gate failure detection circuit has a slightly stricter layout pattern sizes than those of the memory cell 17 of the memory cell array 15. The gate failure detection circuit has the same circuit configuration and function as the memory cell 17 of the memory cell array 15, except for the layout pattern sizes of the gate layer. As illustrated in FIG. 3, the layout sizes of the gate layer of the gate failure detection circuit are also determined to be close to upper and lower limits defined by product manufacturing standards.

Considering manufacturing variability, it is naturally presumable that process failure detection circuits 18 that do not meet the product manufacturing standards may be manufactured. However, since the process failure detection circuits 18 are not used as actual products, even if the process failure detection circuits 18 have functional failures, the overall yield or the product performance is not affected. Further, since a process failure detection circuit 18 shares bit and word lines with the memory cell array 15 and other process failure detection circuits 18, the stricter sizes illustrated in FIG. 2 are determined so that failure modes are not created. The failure modes include a mode in which a current flowing during a non-selection period is increased by functions or failures of these shared parts. For example, when the memory cell 17 is a static random access memory (SRAM) cell and is used as a process failure detection circuit 18, if an input of a cell inverter is open, a pass-through current may flow at all times. While the process failure detection circuit 18 is a circuit that is not used as a product specification, if such pass-through current flows, power consumption of the product is affected. In contrast, for example, when an output of a cell inverter is open, the process failure detection circuit 18 does not function as a memory cell 17. However, since the process failure detection circuit 18 is not used as a product specification, such failure does not affect the product performance. Thus, parts of the process failure detection circuit that need to have stricter pattern sizes are determined in view of possible failure modes.

Further, since the process failure detection circuit 18 is arranged in a dummy region, the process failure detection circuit 18 is affected by a degree of density/sparsity of peripheral pattern. Thus, even if the process failure detection circuit 18 has a layout pattern identical to that of the memory cell 17 of the memory cell array 15, the process failure detection circuit 18 arranged in the periphery to the memory cell array 15 may not exhibit the same characteristics to memory cells 17 arranged in the central part of the memory cell array 15. However, since it is only necessary that the process failure detection circuit be used to be compared with other chips of the same wafer or other wafers for evaluation, the process failure detection circuit 18 does not necessarily exhibit the same characteristics as the memory cell 17 of the memory cell array 15.

FIG. 4 illustrates arrangement of the process failure detection circuits 18 in a plurality of processes in the memory macro 12. In FIG. 4, each of the memory blocks 13 includes process failure detection circuits 18 detecting failures in a different manufacturing process. Second via failure detection circuits of 96 bits (3 bits×32 bits) as illustrated in FIG. 1C are arranged in a second via failure detection circuit arrangement region 21. The second via failure detection circuits are one of the types of the process failure detection circuits 18 and detect failures caused in a second via manufacturing process. Similarly, second metal layer failure detection circuits, first via failure detection circuits, first metal layer failure detection circuits, contact failure detection circuits, gate failure detection circuits, and field failure detection circuits, each of which formed by 96 bits (3 bits×32 bits), are arranged in a second metal layer failure detection circuit arrangement region 22, a first via failure detection circuit arrangement region 23, a first metal layer failure detection circuit arrangement region 24, a contact failure detection circuit arrangement region 25, a gate failure detection circuit arrangement region 26, and a field failure detection circuit arrangement region 27, respectively. The above types of the process failure detection circuits 18 are used as examples, and therefore, the number of manufacturing processes detected by the process failure detection circuits 18 and the number of the types of the process failure detection circuits 18 may be increased as needed.

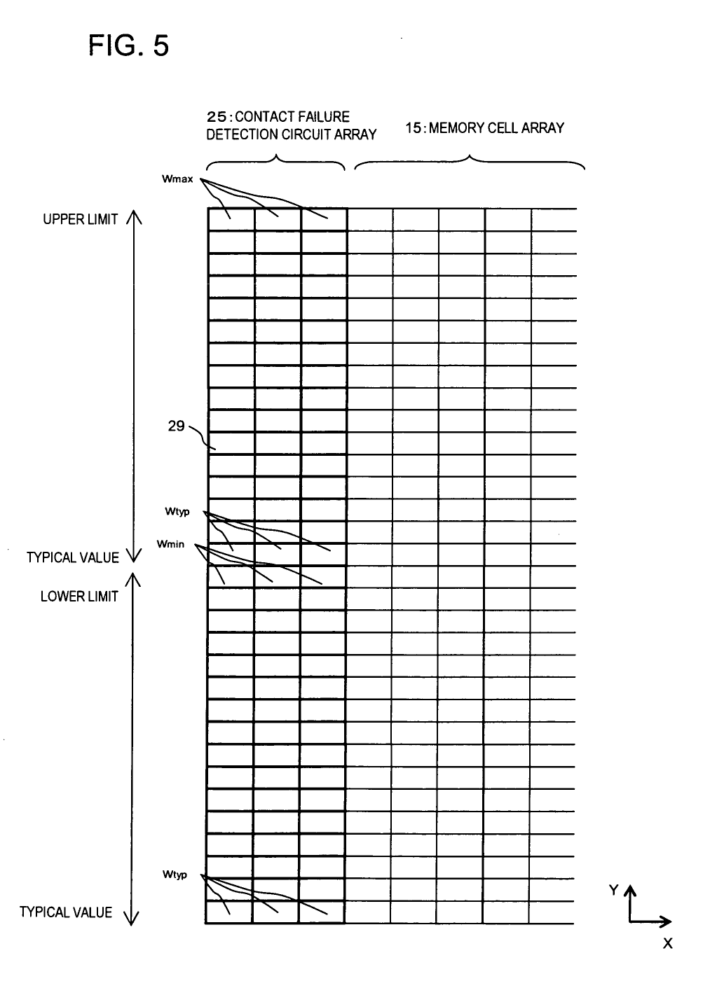

FIG. 5 illustrates arrangement of the process failure detection circuits 18 in one of the many process failure detection circuit arrays (21 to 27) illustrated in FIG. 4. As a specific example, FIG. 5 illustrates arrangement of contact failure detection circuits 29 in the contact failure detection circuit array 25.

Next, pattern sizes of a contact or a via and possible failure modes will be described. FIGS. 6A to 6C illustrate typical values and upper and lower limits of the width of a contact or a via. The following description is based on an example where the typical value of the width of each of the product contacts or vias is determined to be W1, the typical value of the distance between two contacts or vias is D1, and the contacts or the vias are arranged at a regular interval (W1+D1), as illustrated in FIG. 6A.

FIG. 6B illustrates a pattern when the width of the contact or via in FIG. 6A is increased from the typical value W1 to W1+α. Assuming that the interval between two contacts or vias (W1+D1) is constant, an increase of the width of a contact or a via narrows the distance D1 between two contacts or vias to be D1−α. As a result, two contacts or vias short out easily.

In contrast, as illustrated in FIG. 6C, when the typical value W1 of the contact or via is decreased to W1−α, the distance D1 between two contacts or vias is increased to D1+α. As a result, a pass-through current may not flow through each contact or via. Thus, for example, as long as the contacts or vias are arranged at a regular interval, if a pattern value is increased from a typical value and exceeds the upper limit of an allowable range, a failure is caused. Similarly, if a pattern value is decreased from the typical value and exceeds the lower limit of the allowable range, a failure is caused.

Therefore, as the contact failure detection circuits 29 in FIG. 5, two types of process failure detection circuits 18 need to be arranged, such as contact failure detection circuits 29 having a contact width typical value W1 increased toward an upper limit of a manufacturing standard and contact failure detection circuits 29 having a contact width typical value W1 decreased toward a lower limit of the manufacturing standard.

Referring back to FIG. 5, among the 32 contact failure detection circuits 29 arranged along the Y-axis in the contact failure detection circuit arrangement region 25, contact failure detection circuits 29 having a contact width that is closest to the upper limit of a manufacturing standard (contact width: Wmax) are arranged in an uppermost row along the Y-axis. From below the uppermost row, 16 contact failure detection circuits 29 are arranged so that the contact widths thereof are gradually decreased along the Y-axis. The contact width of the 16th contact failure detection circuits 29 has a typical value Wtyp. Below the contact failure detection circuits 29 having a contact width of the typical value Wtyp (downwards along the Y-axis), contact failure detection circuits 29 having a contact width that is closest to the lower limit of the manufacturing standard (contact width: Wmin) are arranged. Further, from below the contact failure detection circuits 29 having the lower limit contact width Wmin, contact failure detection circuits 29 are arranged so that the contact widths thereof are gradually increased. In a lowermost row along the Y-axis, contact failure detection circuits 29 having the typical contact width Wtyp are arranged.

Three contact failure detection circuits 29 arranged along the X-axis in each row may have an identical contact size or different contact sizes. Additionally, while the 16th and the 32nd contact failure detection circuits 29 from the uppermost section have the identical contact size Wtyp, since 32 contact failure detection circuits 29 are arranged along the Y-axis, 32 contact failure detection circuits 29 having 31 different types of contact sizes can be arranged. However, if such contact failure detection circuits having many different types of contact sizes as described above cannot be arranged, two types of contact failure detection circuits 29 may be arranged, that is, contact failure detection circuits 29 having a contact size increased toward an upper limit of a manufacturing standard from a typical value and contact failure detection circuits 29 having a contact size decreased toward a lower limit of the manufacturing standard from the typical value. In this way, evaluation or control of manufacturing conditions can be carried out.

FIG. 9 is a flow chart illustrating a method of controlling manufacture of the semiconductor device 11 including the process failure detection circuits 18. With reference to FIG. 9, how wafer-level manufacturing processes of the semiconductor device 11 are controlled by using the process failure detection circuits 18 will be described. Based on the semiconductor device 11 including the process failure detection circuits 18, an appropriate process failure detection circuit 18 is used in each of the wafer-level manufacturing processes for a surface inspection (or appearance inspection), so as to control each of the manufacturing processes (step S1). For example, for the control of the field layer manufacturing process, the field layer of the field failure detection circuit array 27 has a stricter layout pattern regarding manufacturing conditions, compared with that of the field layer of the memory cell array 15. Thus, by carrying out a surface inspection on the field failure detection circuit array 27 after the field layer manufacturing process, failures caused in the field layer manufacturing process can be detected promptly. If a failure is detected by the surface inspection of the field failure detection circuit array 27, whether or not the appearance failure causes a product failure is examined. If it is determined that the appearance failure causes a product failure, the field layer manufacturing process is provided with feedback, and manufacturing conditions of the field layer manufacturing process are modified so that such failures are not caused in the process (step S2).

After the wafer-level manufacturing processes, a function test is carried out on the wafer-level semiconductor device 11 by using an LSI tester (step S3). In this function test, the process failure detection circuits 18 are also tested. However, generally, failures of the process failure detection circuits 18 do not directly result in product failures, and thus, the test results of the process failure detection circuits 18 are managed separately from those of the product wafer. If no problems are found by these tests of the product and the process failure detection circuits 18, the next manufacturing process is carried out. For example, the semiconductor device 11 is next separated from the semiconductor wafer and built in a package (step S4).

In the wafer test (step S3), if failures are detected by the tests of the product or the process failure detection circuits 18, in order to investigate whether or not certain manufacturing processes are problematic, failure cells are investigated (step S5). Particularly, if a failure is detected by the test of the process failure detection circuits 18, investigation is carried out to find which process failure detection circuits 18 detect the failure and which manufacturing process causes the failure. If a plurality of types of process failure detection circuits 18 are used in a single manufacturing process; for example, those having upper-limit-side sizes and those having lower-limit-side sizes, investigation is carried out to determine what failure is caused in which process failure detection circuit.

As one method for such investigation, as illustrated in FIG. 7, a failure bit map may be created for each of the process failure detection circuits 18 of different processes. In FIG. 7, a plurality of test results of the semiconductor device 11 are used, and positions of the failure detection circuits detected as failures are aligned and indicated in the form of a bit map. In FIG. 7, positions of the process failure detection circuits 18 determined as failures by the test results are indicated by x marks as failure bits 49. In each memory block 13, the process failure detection circuits 18 of a relevant manufacturing process are arranged in a region. Thus, in FIG. 7, the arrangement of the process failure detection circuits 18 for each of the manufacturing processes is indicated in the form of a bit map.

In FIG. 7, a second via failure detection circuit bit map region 41, a second metal layer failure detection circuit bit map 42, a first via failure detection circuit bit map region 43, a first metal layer failure detection circuit bit map region 44, a contact failure detection circuit bit map region 45, a gate failure detection circuit bit map region 46, and a field failure detection circuit bit map region 47 are arranged to illustrate the failures caused in the process failure detection circuit arrays 21 to 27 of FIG. 4, respectively. In addition, the failures are displayed at positions corresponding to the layout in FIG. 5 or the like, so that the cell positions of the failures can also be determined in each process failure detection circuit array. For example, in FIG. 7, since the contact failure detection circuit bit map region 45 includes many x marks, it can be seen that many failures are caused in the contact failure detection circuit. More specifically, in the contact failure detection circuit bit map region 45, x marks are concentrated from the central to the lower region along the Y-axis. Thus, by referring to FIG. 5, it can be seen that many failures are caused in the contact failure detection circuits having a contact size of the lower limit or near the lower limit.

Other than the block-level bit maps or product-level bit maps as illustrated in FIG. 7, as illustrated in FIG. 8, wafer-level bit maps may be created. FIG. 8A illustrates a wafer-level product bit map 51 indicating positions of the semiconductor devices 11 determined as failures by the product test on the semiconductor wafer 55. In FIG. 8A, the positions of the semiconductor device 11 determined as failures are denoted by x marks as failure chip positions 54 on the semiconductor wafer 55.

FIG. 8B is a field failure detection circuit bit map 52 indicating wafer-level failure positions of the field failure detection circuits included in the field failure detection circuit array 27. FIG. 8C is a contact failure detection circuit bit map 53 indicating wafer-level failure positions of the contact failure detection circuits included in the contact failure detection circuit array 25. In FIGS. 8B and 8C, as in FIG. 8A, the failure chip positions 54 are indicated by x marks. When FIGS. 8A to 8C are compared, it can be seen that the product bit map 51 of FIG. 8A shows that many product failures are concentrated in the central part of the semiconductor wafer 55, the field failure detection circuit bit map 52 of FIG. 8B shows that failures of the field failure detection circuits are scattered in the peripheral part of the semiconductor wafer 55, and the contact failure detection circuit bit map 53 of FIG. 8C shows that failures of the contact failure detection circuits are concentrated in the central part of the semiconductor wafer 55. The wafer-level bit maps as described above may be created as the need arises; for example, wafer-level process failure detection circuit bit maps may be created for manufacturing processes causing failures.

The flow chart of FIG. 9 illustrating the method for controlling manufacture of the semiconductor device 11 will be referred to again. In step S6, wafer in-plane tendency is investigated in view of the occurrence frequency of failures. In this step S6, the wafer in-plane tendency of the failure product and process failure detection circuits is investigated by using wafer-level failure bit maps as illustrated in FIGS. 8A to 8C (to determine whether failures are caused in the central or peripheral part of the semiconductor wafer, for example). For example, in the examples of FIGS. 8A to 8C, while the product bit map 51 shows that failures are caused in the central part of the wafer, the field failure detection circuit bit map 52 shows that failures are caused in the periphery part of the wafer. Thus, it is presumable that the product failures are not directly attributable to the field process. However, since the contact failure detection circuit bit map 53 shows that many failures are caused in the central part of the semiconductor wafer 55, it is presumable that the product failures are attributable to the contact manufacturing process. In such case, since there is a correlation between the product bit map 51 and the contact failure detection circuit bit map 53, the contact manufacturing process, which is the relevant matching process in this case, can be provided with feedback and the manufacturing conditions can be modified (step S7).

In contrast, when no correlation between the wafer-level product bit map and the failure detection circuit bit maps of any one of the manufacturing processes is obtained, an appearance failure inspection is carried out on the entire semiconductor device 11 and the process failure detection circuit arrays 16 (step S8). If any problems are found, the relevant manufacturing processes are provided with feedback (step S9), and if not, the operation proceeds to the next process (step S10).

As described above, a semiconductor device according to the present invention uses process failure detection circuits to find problems with manufacturing processes promptly and easily, and as a result, problematic manufacturing processes can be provided with feedback. Further, since the process failure detection circuits are arranged in a dummy region around the cell array, the chip area is not increased. Furthermore, since the process failure detection circuits are arranged at the same intervals as the cells of the cell array and are formed substantially identical to the cells of the cell array, the process failure detection circuits are allowed to function as a dummy pattern.

In the above example, a specific example where the cell array is a memory cell array has been described. However, other than the memory cell array, the present invention is applicable to a cell array of resistance cells or power supply cells used in an AD converter or digital-to-analog (DA) converter. As in the case where the process failure detection circuits are arranged around the memory cell array, by arranging a layout pattern having a shape substantially identical to the above resistance cell or power supply cell in a dummy region arranged around a cell array, the process failure detection circuits can be formed. Further, the process failure detection circuits can be tested by allowing the AD converter or DA converter to treat the process failure detection circuits as resistance cells or power supply circuit cells. Namely, the present invention is applicable to various types of cell arrays other than a memory cell array, as long as the cell array is formed by regularly arranging cells of an identical shape and a dummy region is arranged around the cell array.

While the example has thus been described, the present invention is not merely limited to the above example. The present invention of course includes various variations and modifications that could be made by those skilled in the art within the scope of the present invention.

What is claimed is:

1. A semiconductor device comprising:
a cell array; and
a plurality of process failure detection circuits each having a layout pattern substantially identical to that of a cell of the cell array in a dummy region arranged around the cell array.

2. The semiconductor device according to claim 1, wherein each of the process failure detection circuits in the dummy region comprises:
a dummy pattern that equalizes a degree of density/sparsity of a peripheral part of the cell array with that of a central part of the cell array.

3. The semiconductor device according to claim 1, wherein the plurality of the process failure detection circuits comprise:
a process failure detection circuit having a layout pattern formed with a stricter pattern margin in at least one manufacturing process, compared with the layout pattern of the cell of the cell array.

4. The semiconductor device according to claim 1, wherein the plurality of the process failure detection circuits comprise:
a plurality types of the process failure detection circuits, each type of the plurality types of the process failure detection circuits having a layout pattern formed with a stricter pattern margin in a different manufacturing process, compared with the layout pattern of the cell of the cell array.

5. The semiconductor device according to claim 4, wherein the plurality types of the process failure detection circuits comprise:
a wiring process failure detection circuit including a stricter wiring pattern compared with the wiring pattern of the cell of the cell array, said wiring pattern including any of wiring and via patterns; and
a base layer process failure detection circuit including a stricter base layer pattern compared with the base layer pattern of the cell of the cell array, said base layer pattern including any of gate, contact, and field patterns.

6. The semiconductor device according to claim 3, wherein the process failure detection circuits comprise:
a first process failure detection circuit having a layout pattern formed by increasing a first pattern size toward an upper limit and decreasing a second pattern size toward a lower limit; and
a second process failure detection circuit having a layout pattern formed by decreasing the first pattern size toward a lower limit and increasing the second pattern size toward an upper limit, wherein the sum of the first pattern size and the second pattern size is fixed.

7. The semiconductor device according to claim 1, wherein the cell array is a memory cell array, and each of the plurality of process failure detection circuits shares a read/write circuit with the memory cell array.

8. A method of manufacturing a semiconductor device, the semiconductor device comprising a cell array and a plurality of types of process failure detection circuits, each having a layout pattern substantially identical to that of a cell of the cell array in a dummy region around the cell array, each type of the process failure detection circuit having a layout pattern formed with a stricter pattern margin in a different manufacturing process of the semiconductor device, compared with the layout pattern of the cell of the cell array, the method comprising:
carrying out a surface inspection of a first process by using a first type process failure detection circuit of the plurality types of the process failure detection circuit, the first type process failure detection circuit having a layout pattern formed with a stricter pattern margin in the first process pattern, the first process being a one process in a wafer-level manufacturing processes of the semiconductor device;
providing feedback about a manufacturing condition to the first process when a problem is found in the surface inspection of the first process;
carrying out a function test on the plurality of types of process failure detection circuits after completion of the wafer-level manufacturing processes;
determining a problematic manufacturing process by using a result of the function test on the plurality of types of process failure detection circuits when a problem is found in the function test; and
providing feedback about manufacturing condition of the problematic manufacturing process.

9. The method according to claim 8, wherein determining a problematic manufacturing process comprises:
analyzing a position of a failure semiconductor device determined by the function test of a total function of the semiconductor device found on the wafer, the position of the failure for each type of the process failure detection circuit found on the wafer, and failure occurrence frequency; and
determining the problematic manufacturing processes based on a result of the analyzing.

10. The method according to claim 8, wherein the cell array is a memory cell array, and a function test of the process failure detection circuit is carried out by performing read/write access to the process failure detection circuit via the memory cell array.
